(19) United States
(12) Patent Application Publication
(10) Pub. No.: US 2008/0316831 A1
(43) Pub. Date: Dec. 25, 2008

(54) Nonvolatile semiconductor device, system including the same, and associated methods

(76) Inventors: Sung-Chul Park, Seoul (KR); Jeong-Uk Han, Suwon-si (KR); Jae-Hwang Kim, Yongin-si (KR); Ju-Ri Kim, Hwaseong-si (KR)

Correspondence Address: LEE & MORSE, P.C., 3141 FAIRVIEW PARK DRIVE, SUITE 500, FALLS CHURCH, VA, 22042, US

(21) Appl. No.: 12/213,278

(22) Filed: Jun. 17, 2008

(30) Foreign Application Priority Data
Jun. 20, 2007 (KR) 10-2007-0060573

(51) Int. Cl. G11C 16/06; G11C 11/34; H01L 21/336; H01L 29/788

(52) U.S. Cl. 365/185.18; 365/174; 438/264; 257/315; 257/E21.409; 257/E29.3

(57) ABSTRACT

A nonvolatile memory device is provided. The nonvolatile memory device includes a semiconductor substrate and memory cell units arranged in a matrix on the semiconductor substrate. Each of the memory cell units includes a tunnel insulation layer on the semiconductor substrate. A first memory gate and a second memory gate are disposed on the tunnel insulation layer. An isolation gate is disposed between the first and second memory gates. A word line covers the first memory gate, the second memory gate and the isolation gate. A method of forming the nonvolatile memory device is also provided.

### BACKGROUND OF THE INVENTION

1. Field of the Invention

Example embodiments relate a nonvolatile memory device, a system including the same, and associated methods.

2. Description of the Related Art

An EEPROM device may exhibit excellent long-term reliability if the EEPROM device is programmed and erased using a Fowler-Nordheim (FN) tunneling mechanism. However, a unit cell of such an EEPROM device may include two transistors, for example, a selection transistor and a memory transistor. Further, a unit cell of the EEPROM device may store only a single bit of data. Accordingly, there may be limitations in increasing the degree of integration of such an EEPROM device.

A unit cell of a NOR-type flash memory device may include only a single transistor. Accordingly, it may be easy to increase the integration density and operational speed of such a NOR-type flash memory device. However, the conventional NOR-type flash memory device may be programmed using a channel hot electron injection (CHEI) mechanism, rather than a Fowler-Nordheim (FN) tunneling mechanism. This may degrade the long-term reliability of the device, and may require a large programming current.

### SUMMARY OF THE INVENTION

Embodiments are therefore directed to a nonvolatile memory device, a system including the same, and associated methods, which substantially overcome one or more of the problems due to the limitations and disadvantages of the related art.

It is therefore a feature of an embodiment to provide a nonvolatile memory device having an isolation gate line and associated methods.

It is therefore another feature of an embodiment to provide a method of programming and erasing a nonvolatile memory device having an isolation gate, and a system implementing the same.

At least one of the above and other features and advantages may be realized by providing a nonvolatile memory device, including a semiconductor substrate, and a plurality of memory cell units on the substrate. Each of the memory cell units may include a tunnel insulation layer on the substrate, a first memory gate and a second memory gate on the tunnel insulation layer, the first and second memory gates being spaced apart from each other, an isolation gate line between the first and second memory gates, and a word line on the first memory gate, the second memory gate, and the isolation gate line.

The nonvolatile memory device may further include a first inter-gate dielectric layer between the first memory gate and the isolation gate line, and between the second memory gate and the isolation gate line. The nonvolatile memory device may further include a second inter-gate dielectric layer between the first memory gate and the word line, between the second memory gate and the word line, and between the isolation gate line and the word line.

The word line may be coupled to first and second memory gates of first and second memory cell units, and the isolation gate line may extend between the first and second memory gates of the first memory cell unit, and between the first and second memory gates of the second memory cell unit. The substrate may include an active region, the active region may include at least one protruding extension part, an impurity region may extend into the extension part, and a bit line contact may be electrically connected to the impurity region, the electrical connection being at least partially in the extension part.

At least one of the above and other features and advantages may also be realized by providing a nonvolatile memory system, including a semiconductor substrate, a plurality of memory cell units on the substrate, and a memory controller electrically connected to the plurality of memory cell units. Each of the memory cell units may include a tunnel insulation layer on the substrate, a first memory gate and a second memory gate on the tunnel insulation layer, the first and second memory gates being spaced apart from each other, an isolation gate line between the first and second memory gates, and a word line on the first memory gate, the second memory gate, and the isolation gate line.

The controller may be configured to program and erase the memory cell units using Fowler-Nordheim tunneling. The controller may be configured to float the isolation gate line of a selected memory cell unit during a program operation that writes data to both the first and second memory gates of the selected memory cell unit. The controller may be configured to apply a ground voltage to the isolation gate line of a selected memory cell unit during a program operation that writes data to one of the first and the second gates of the selected memory cell unit.

During the program operation, the controller may apply a program voltage to the word line of the selected memory cell unit, and apply a ground voltage to a bit line electrically connected to a selected memory transistor that includes the first memory gate of the selected memory cell unit when writing data to the first memory gate.

The controller may be configured to float the isolation gate line of the selected memory cell unit during an erase operation that erases data from the selected memory cell unit. During the erase operation, the controller may apply an erasure voltage to the word line of the selected memory cell unit, and apply a ground voltage to first and second bit lines electrically connected to respective first and second memory transistors that include the first memory gate and the second memory gate of the selected memory cell unit.

The controller may be configured to apply a read voltage to the word line and the isolation gate line of the selected memory cell unit during a read operation that reads data stored in the selected memory cell unit. During the read operation, the controller may apply a ground voltage to a bit line coupled to a memory transistor that includes one of the first and second memory gates of the selected memory cell unit, apply a drain voltage to a bit line electrically connected to a memory transistor that includes the other of the first and second memory gates of the selected memory cell unit, and apply the ground voltage to the bit line of the memory transistor being read.

At least one of the above and other features and advantages may also be realized by providing a method of forming memory cell units on a semiconductor substrate, the method including forming a tunnel insulation layer on the substrate, forming a first memory gate and a second memory gate on the tunnel insulation layer, the first and the second memory gates being spaced apart from each other, forming an isolation gate line between the first and the second memory gates, and forming a word line on the first memory gate, the second memory gate, and the isolation gate line.

Forming the first and second memory gates, the isolation gate line, and the word line may include forming a first preliminary memory gate pattern and a second preliminary memory gate pattern on the tunnel insulation layer, the first and second preliminary memory gate patterns being spaced apart from each other, forming the isolation gate line in a space between the first and second preliminary memory gate patterns, forming the word line on the isolation gate line and on the first and second preliminary memory gate patterns, the word line being formed to fully cover the isolation gate line, and etching the first and second preliminary memory gate patterns using the word line as an etching mask.

The method may further include forming a first inter-gate dielectric layer between the first memory gate and the isolation gate line, and between the second memory gate and the isolation gate line. The method may further include forming a second inter-gate dielectric layer between the first memory gate and the word line, between the second memory gate and the word line, and between the isolation gate line and the word line.

The method may further include forming an active region in the substrate, the active region including at least one protruding extension part, forming an impurity region that extends into the extension part, and forming a bit line contact that is electrically connected to the impurity region, the electrical connection being formed at least partially in the extension part. The word line may be formed to extend across first and second memory gates of first and second memory cell units, and the isolation gate line may be formed to extend between the first and second memory gates of the first memory cell unit, and between the first and second memory gates of the second memory cell unit.

### BRIEF DESCRIPTION OF THE DRAWINGS

The above and other features and advantages will become more apparent to those of skill in the art by describing in detail example embodiments with reference to the attached drawings, in which:

FIG. 1A illustrates a plan view of a memory cell unit of a nonvolatile memory device according to an embodiment;

FIG. 1B illustrates a plan view of a memory cell unit of a nonvolatile memory device according to another embodiment;

FIG. 2 illustrates a cross sectional view taken along a line I-I′ of FIG. 1A;

FIG. 3 illustrates an equivalent circuit diagram corresponding to the device illustrated in FIGS. 1A and 1B;

FIGS. 4A to 4C illustrate layout diagrams of memory cell arrays of nonvolatile memory devices according to embodiments;

FIG. 5 illustrates an equivalent circuit diagram of the devices illustrated in FIGS. 4A to 4C;

FIGS. 6A to 6C illustrate program bias conditions applied to the nonvolatile memory device of FIG. 5;

FIG. 7 illustrates an erasure bias condition applied to the nonvolatile memory device of FIG. 5;

FIGS. 8A and 8B illustrate read bias conditions applied to the nonvolatile memory device of FIG. 5;

FIGS. 9A to 9C illustrate cross sectional views of stages in a method of forming a nonvolatile memory device according to an embodiment; and

FIG. 10 illustrates a schematic of a memory system according to an embodiment.

### DETAILED DESCRIPTION OF THE INVENTION

Korean Patent Application No. 10-2007-0060573, filed on Jun. 20, 2007, in the Korean Intellectual Property Office, and entitled: “Nonvolatile Semiconductor Devices and Methods of Forming the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

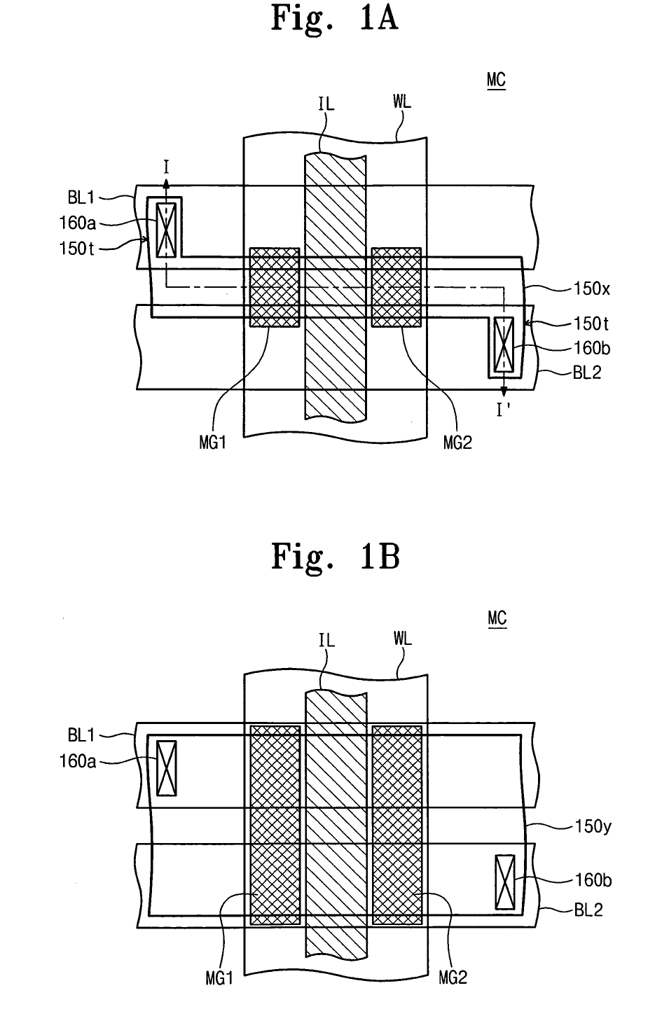

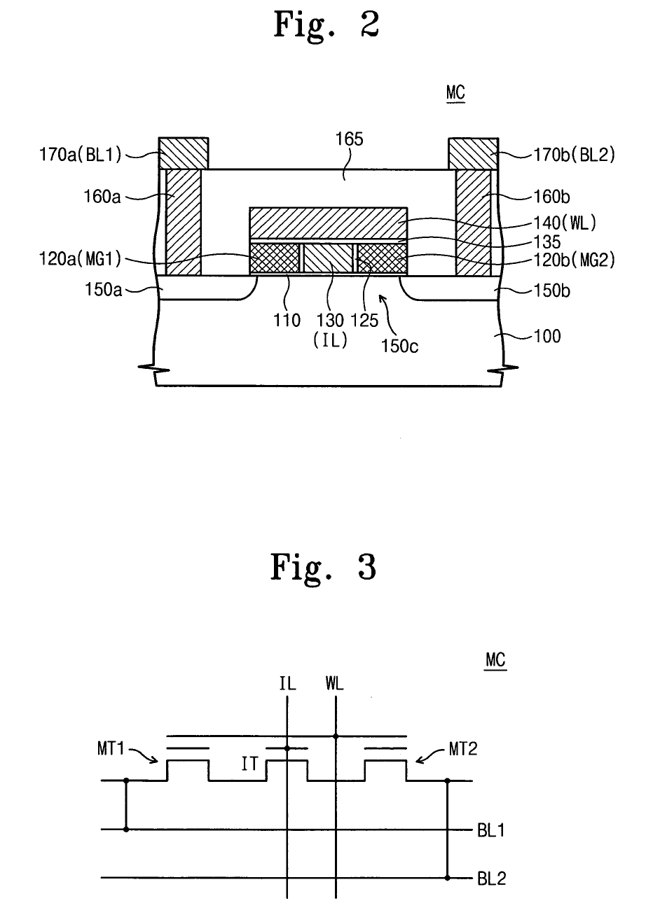

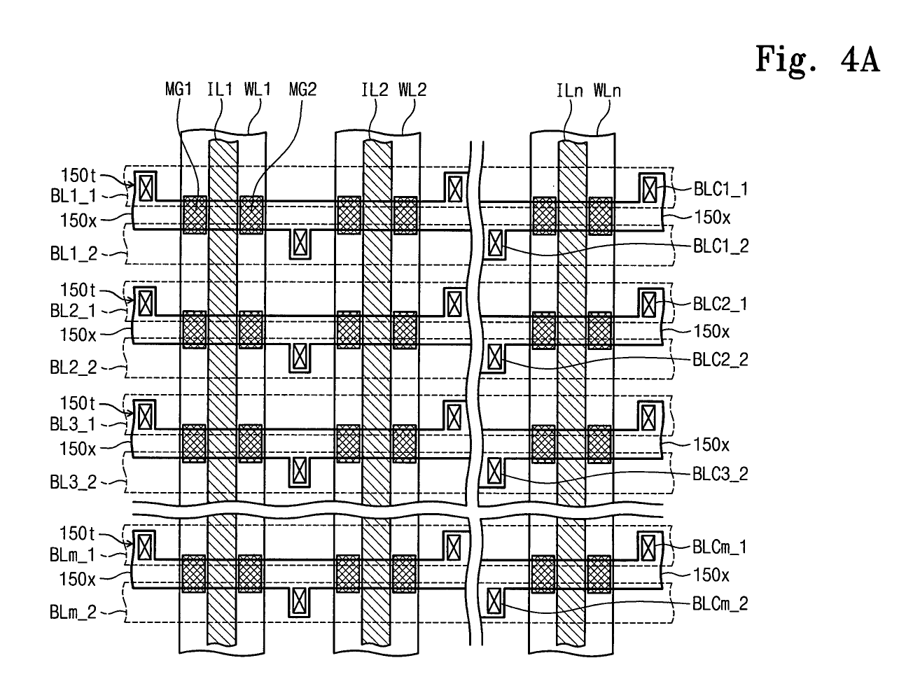

FIG. 1A illustrates a plan view of a memory cell unit of a nonvolatile memory device according to an embodiment, and FIG. 1B illustrates a plan view of a memory cell unit of a nonvolatile memory device according to another embodiment. FIG. 2 illustrates a cross sectional view taken along a line I-I′ of FIG. 1A, and FIG. 3 illustrates an equivalent circuit diagram corresponding to the devices illustrated in FIGS. 1A and 1B.

Referring to FIG. 1A, FIG. 2 and FIG. 3, a memory cell unit MC may include a device isolation layer (not shown) formed in a semiconductor substrate 100 to define an active region 150x. A first memory gate 120a (MG1) and a second memory gate 120b (MG2) may be disposed to cross over the active region 150x, and may be spaced apart from each other when viewed from a plan view as illustrated in FIG. 1A. An isolation gate line 130 (IL) may be disposed between the first and second memory gates 120a (MG1) and 120b (MG2). The isolation gate line 130 (IL) may prevent a disturbance occurring between the first memory gate 120a (MG1) and the second memory gate 120b (MG2), i.e., may help isolate the memory gates, during operation of the memory device.

The first memory gate 120a (MG1), the second memory gate 120b (MG2) and the isolation gate line 130 (IL) may be electrically insulated from the active region 150x by a tunnel insulating layer 110 provided on the active region 150x. The tunnel insulation layer 110 may include, e.g., a silicon oxide layer. The first memory gate 120a (MG1), the second memory gate 120b (MG2), the isolation gate line 130 (IL) and the word line 140 (WL) may be formed of a same material, e.g., polysilicon.

A word line 140 (WL) may cover the first memory gate 120a (MG1), the second memory gate 120b (MG2) and the isolation gate line 130 (IL). The word line 140 (WL) may extend lengthwise in parallel with the isolation gate line 130 (IL).

The first memory gate 120a (MG1) and the second memory gate 120b (MG2) may each include a floating gate, a nano-dot layer, a charge trap layer, or a combination of the nano-dot layer and the charge trap layer. In the case that the first and second memory gates 120a (MG1) and 120b (MG2) include floating gates, the first and second memory gates 120a (MG1) and 120b (MG2) may include a conductive layer, for example, a doped polysilicon layer. In the case that the first and second memory gates 120a (MG1) and 120b (MG2) include nano-dot layers, the first and second memory gates 120a (MG1) and 120b (MG2) may include an insulation layer having a plurality of dot-shaped conductors or a plurality of dot-shaped insulators therein. In the case that the first and second memory gates 120a (MG1) and 120b (MG2) include charge trap layers, the first and second memory gates 120a (MG1) and 120b (MG2) may include a silicon nitride layer, an aluminum oxide layer, a hafnium aluminate (HfAlO) layer, a hafnium aluminum oxynitride (HfAlON) layer, a hafnium silicate (HfSiO) layer or a hafnium silicon oxynitride (HfSiON) layer as the charge trap layer.

A first inter-gate dielectric layer 125 may be disposed between the first memory gate 120a (MG1) and the isolation gate line 130 (IL), as well as between the second memory gate 120b (MG2) and the isolation gate line 130 (IL). The first inter-gate dielectric layer 125 may include, e.g., a silicon oxide layer. A second inter-gate dielectric layer 135 may be disposed between the first memory gate 120a (MG1) and the word line 140 (WL), between the second memory gate 120b (MG2) and the word line 140 (WL), and between the isolation gate line 130 (IL) and the word line 140 (WL).

In an implementation, the dielectric constant of the second inter-gate dielectric layer 135 may be higher than that of the first inter-gate dielectric layer 125. The second inter-gate dielectric layer 135 may include, e.g., a material layer having a relatively high dielectric constant such as an oxide-nitride-oxide (ONO) layer. In another implementation, the second inter-gate dielectric layer 135 may include a silicon oxide layer, a silicon nitride layer, an aluminum oxide layer, a hafnium aluminate (HfAlO) layer, a hafnium aluminum oxynitride (HfAlON) layer, a hafnium silicate (HfSiO) layer, a hafnium aluminum oxynitride (HfSiON) layer, or a combination thereof.

A first impurity region 150a may be provided in the active region 150x adjacent to the first memory gate 120a (MG1) and opposite the second memory gate 120b (MG2). Similarly, a second impurity region 150b may be provided in the active region 150x adjacent to the second memory gate 120b (MG2) and opposite the first memory gate 120a (MG1). The active region 150x between the first and second impurity regions 150a and 150b may act as a channel region 150c. A first interlayer dielectric layer 165 may be provided to cover the word line 140 (WL), the first impurity region 150a and the second impurity region 150b.

A first bit line 170a (BL1) may be disposed on the first interlayer dielectric layer 165. The first bit line 170a (BL1) may be electrically connected to the first impurity region 150a through a first bit line contact 160a that penetrates the first interlayer dielectric layer 165. The first bit line 170a (BL1) may extend to cross over the word line 140 (WL), i.e., the first bit line 170a (BL1) may extend along a longitudinal direction of the active region 150x.

A second bit line 170b (BL2) may also be disposed on the first interlayer dielectric layer 165. The second bit line 170b (BL2) may be electrically connected to the second impurity region 150b through a second bit line contact 160b that penetrates the first interlayer dielectric layer 165. The second bit line 170b (BL2) may also extend to cross over the word line 140 (WL), i.e., the second bit line 170b (BL2) may extend along a longitudinal direction of the active region 150x.

In an embodiment, the active region 150x may include an extension part 150t that protrudes from at least one end of the active region 150x. In an implementation, the extension part 150t may be a generally rectangular extension with a major axis parallel to the word line 140 (WL). At least one of the first and second impurity regions 150a and 150b may be formed completely or partially in the extension part 150t. The first bit line contact 160a or the second bit line contact 160b may be electrically connected to the extended impurity region 150a or 150b formed in the extension part 150t.

If the active region 150x includes two extension parts 150t protruding from respective ends of the active region 150x, one extension part 150t may protrude in a first direction parallel to the word line WL and the other extension part 150t may protrude in a second direction that is opposite to the first direction, as illustrated in FIG. 1A.

The first impurity region 150a, the channel region 150c and the first memory gate 120a (MG1) may constitute a first memory transistor MT1. Similarly, the second impurity region 150b, the channel region 150c and the second memory gate 120b (MG2) may constitute a second memory transistor MT2. The channel region 150c and the isolation gate line 130 (IL) may constitute an isolation transistor IT. Accordingly, the memory cell unit MC may include two memory transistors MT1 and MT2, and an isolation transistor IT. Therefore, the memory cell may be capable of storing two bits of data. As a result, it may be possible to increase the degree of integration of the nonvolatile memory device.

Referring to FIG. 1B, a nonvolatile memory device according to another embodiment will now be described. This embodiment may differ from the embodiment described above in connection with FIG. 1A, in that an active region 150y may be shaped differently. In particular, the active region 150y may have a greater width than the active region 150x of the embodiment described above in connection with FIG. 1A. The greater width of the active region 150y may increase the effective channel width of the memory transistors MT1 and MT2, which may allow a large cell current to flow. The active region 150y may not include any extension parts 150t.

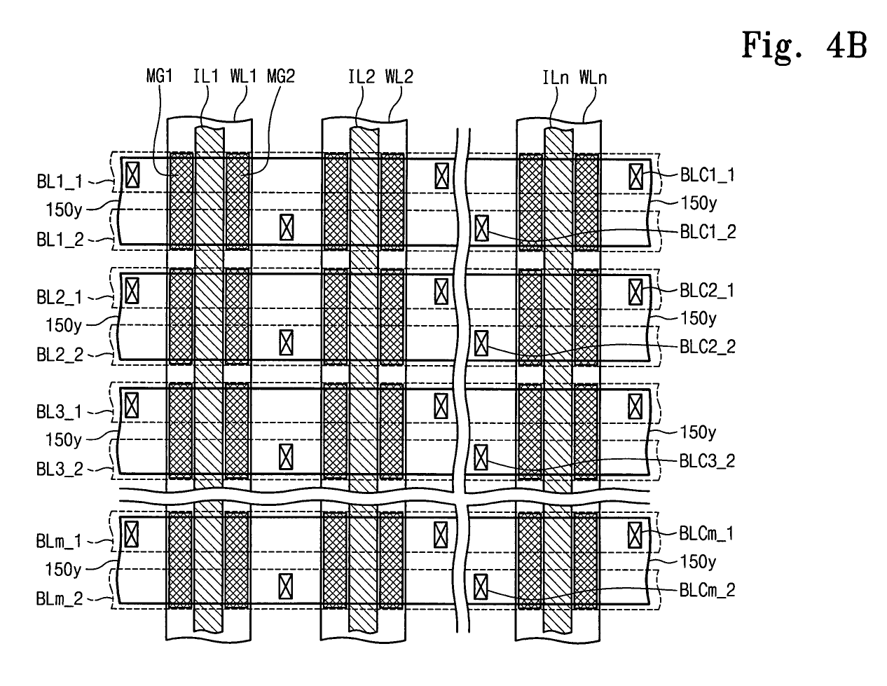

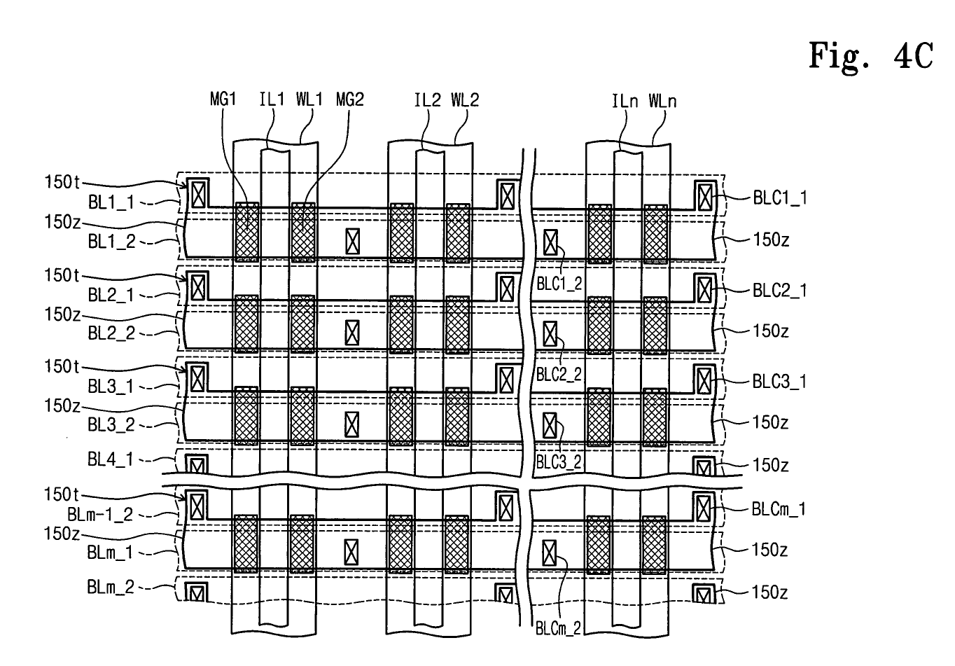

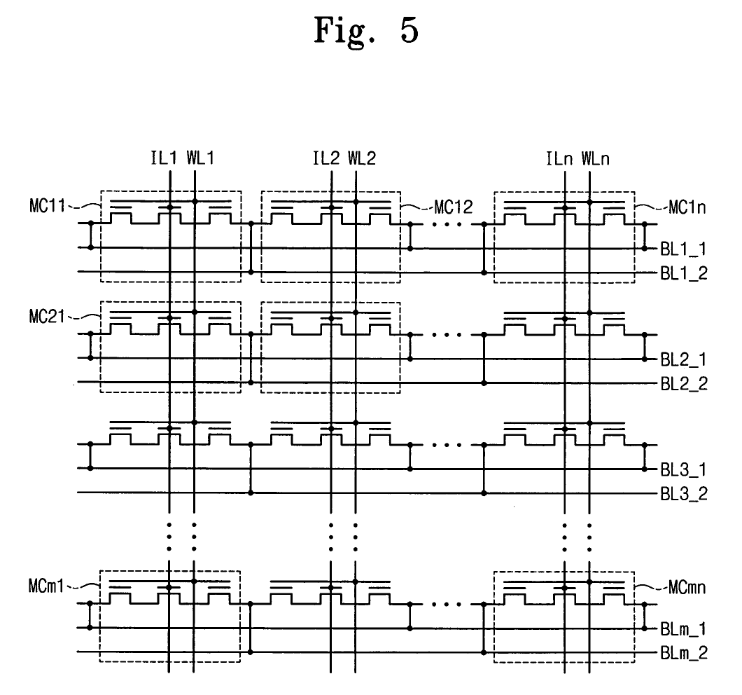

FIGS. 4A to 4C illustrate layout diagrams of memory cell arrays of nonvolatile memory devices according to embodiments, and FIG. 5 illustrates an equivalent circuit diagram of the devices illustrated in FIGS. 4A to 4C.

Referring to FIG. 4A and FIG. 5, the nonvolatile memory device may include a plurality of memory cell units MC11˜MCm1, MC12˜MCm2, . . . and MC1n˜MCmn. The memory cell units may be arranged in a matrix along a row-direction and a column-direction on a semiconductor substrate.

A device isolation layer (not shown) may be provided in the semiconductor substrate to define active regions 150x. Each of the active regions 150x may extend lengthwise along a first direction, e.g., the row-direction, and may include extension parts 150t like those described above in connection with FIG. 1A. A plurality of extension parts 150t may extend from a single active region 150x. In an implementation, the extension parts 150t may extend alternately from opposing sides of the single active region 150x, as shown in FIG. 4A.

The plurality of the memory cell units MC11˜MCm1, MC12˜MCm2, . . . and MC1n˜MCmn may be provided on the active regions 150x. Each of the memory cell units MC11˜MCm1, MC12˜MCm2, . . . and MC1n˜MCmn may have the same structure as illustrated in FIGS. 2A and 3. Thus, the memory cell array may include a plurality of word lines WL1˜WLn which cross over the active regions 150x.

A pair of memory gates, e.g., a first memory gate MG1 and a second memory gate MG2, may be disposed at each of the respective intersections between the word lines WL1˜WLn and the active regions 150x. The first and second memory gates MG1 and MG2 may be spaced apart from each other at the respective intersections of the word lines WL1˜WLn and the active regions 150x, and isolation gate lines IL1˜ILn may be disposed to cross over the active regions 150x between the respective adjacent memory gates MG1 and MG2.

A plurality of first bit lines BL1_1˜BLm_1 and a plurality of second bit lines BL1_2˜BLm_2 may be disposed to cross over the word lines WL1˜WLn. The first bit lines BL1_1˜BLm_1 may be electrically connected to the active regions 150x through a plurality of first bit line contacts BLC1_1˜BLCm_1, and the second bit lines BL1_2˜BLm_2 may be electrically connected to the active regions 150x through a plurality of second bit line contacts BLC1_2˜BLCm_2. The first and second bit line contacts BLC1_1˜BLCm_1 and BLC1_2˜BLCm_2 may be electrically connected to the extension parts 150t of the active region 150x.

Referring to FIG. 4B and FIG. 5, an exemplary memory cell array of a nonvolatile memory device according to another embodiment will now be described. The nonvolatile memory device may include the plurality of memory cell units MC11˜MCm1, MC12˜MCm2, . . . and MC1n˜MCmn arranged in a matrix along a row-direction and a column-direction on the semiconductor substrate. A device isolation layer (not shown) may be provided in the semiconductor substrate to define the active regions 150y. Each of the active regions 150y may extend lengthwise along, e.g., the row-direction. The memory cell units MC11˜MCm1, MC12˜MCm2, . . . and MC1n˜MCmn may be provided on the active regions 150y.

Each of the memory cell units MC11˜MCm1, MC12˜MCm2, . . . and MC1n˜MCmn may have the same structure as illustrated in FIG. 1B. Thus, a plurality of word lines WL1˜WLn may be disposed to cross over the active regions 150y, and the active regions 150y may be wide, rather than including the extension parts 150t that are illustrated in FIG. 4A. Thus, each of the active regions 150y may have a greater width than the active regions 150x illustrated in FIG. 4A.

A pair of memory gates (e.g., a first memory gate MG1 and a second memory gate MG2) may be disposed at the respective intersections between the word lines WL1˜WLn and the active regions 150y, as for the embodiment described above in connection with FIG. 4A. Further, a plurality of isolation gate lines IL1˜ILn may be disposed to cross over the active regions 150y, and each of the isolation gate lines IL1˜ILn may be disposed between first and second memory gates MG1 and MG2 that are adjacent to each other.

A plurality of first bit lines BL1_1˜BLm_1 and a plurality of second bit lines BL1_2˜BLm_2 may be disposed to cross over the word lines WL1˜WLn. The first bit lines BL1_1˜BLm_1 may be electrically connected to the active regions 150y through a plurality of first bit line contacts BLC1_1˜BLCm_1, and the second bit lines BL1_2˜BLm_2 may be electrically connected to the active regions 150y through a plurality of second bit line contacts BLC1_2˜BLCm_2

As described above, the active regions 150y under the first and second memory gates MG1 and MG2 may have a greater width than the active regions 150x illustrated in FIG. 4A, and thus may allow increased cell current as compared to the embodiment described above in connection with FIG. 4A.

Referring to FIG. 4C and FIG. 5, an exemplary memory cell array of a nonvolatile memory device according to another embodiment will now be described. The nonvolatile memory device may include the plurality of memory cell units MC11˜MCm1, MC12˜MCm2, . . . and MC1n˜MCmn arranged in a matrix along a row-direction and a column-direction on a semiconductor substrate. The device isolation layer (not shown) may be provided in the semiconductor substrate to define active regions 150z.

As described above, the active regions 150x may be configured to have extension parts 150t extending off of alternating sides of the active regions 150x, with extension parts 150t connected to the first bit lines BL1_1˜BLm_1 and the second bit lines BL1_2˜BLm_2. In contrast, each of the active regions 150z illustrated in FIG. 4C may have extension parts 150t extending only off a single side of the active region, e.g., connected to the first bit lines BL1_1˜BLm_1, rather than off of alternating sides. Further, the width of the active regions 150z illustrated in FIG. 4C may be greater than the width of the active regions 150x illustrated in FIG. 4A and less than the width of the active regions 150y illustrated in FIG. 4B.

The memory cell units MC11˜MCm1, MC12˜MCm2, . . . and MC1n˜MCmn may be provided on the active regions 150z. Each of the memory cell units MC11˜MCm1, MC12˜MCm2, . . . and MC1n˜MCmn may have the same structure as illustrated in FIGS. 1A and 2. Thus, the memory cell array according to the present embodiment may include the plurality of word lines WL1˜WLn crossing over the active regions 150z. A pair of memory gates, e.g., a first memory gate MG1 and a second memory gate MG2, may be disposed at the respective intersections between the word lines WL1˜WLn and the active regions 150z. The first and second memory gates MG1 and MG2 may be spaced apart from each other at the respective intersections of the word lines WL1˜WLn and the active regions 150z, and respective ones of a plurality of isolation gate lines IL1˜ILn may be disposed to cross over the active regions 150z between the adjacent first and second memory gates MG1 and MG2.

The plurality of first bit lines BL1_1˜BLm_1 and the plurality of second bit lines BL1_2˜BLm_2 may be disposed to cross over the word lines WL11˜WLn. The first bit lines BL1_1˜BLm_1 may be electrically connected to the extension parts 150t of the active regions 150z through the plurality of first bit line contacts BLC1_1˜BLCm_1, and the second bit lines BL1_2˜BLm_2 may be electrically connected to the active regions 150z through the plurality of second bit line contacts BLC1_2˜BLCm_2.

According to the present embodiment, the width of the active regions 150z under the first and second memory gates MG1 and MG2 may be greater than that of the active regions 150x described above in connection with FIG. 4A, and thus may allow increased cell current as compared to the embodiment described above in connection with FIG. 4A.

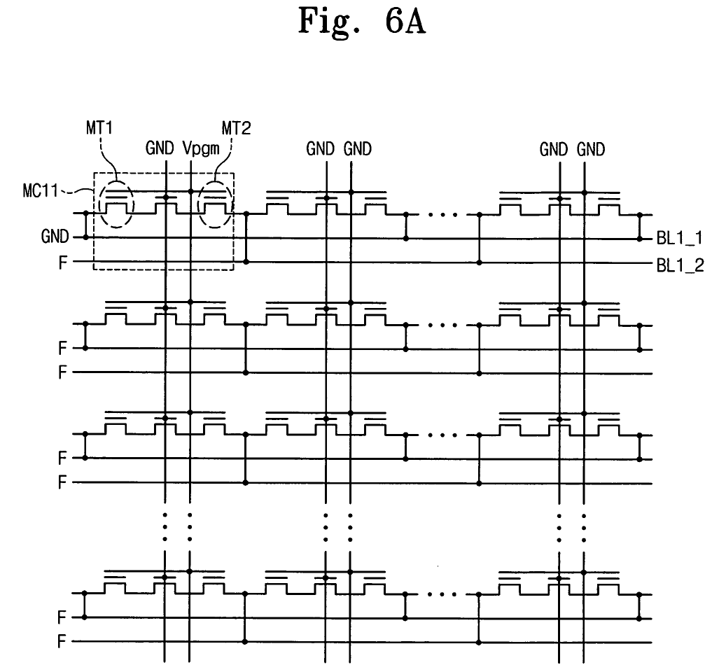

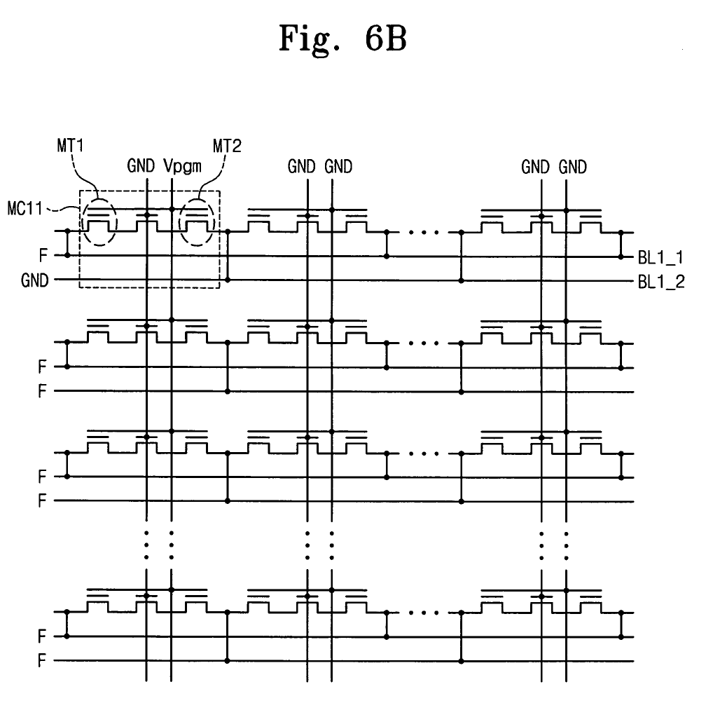

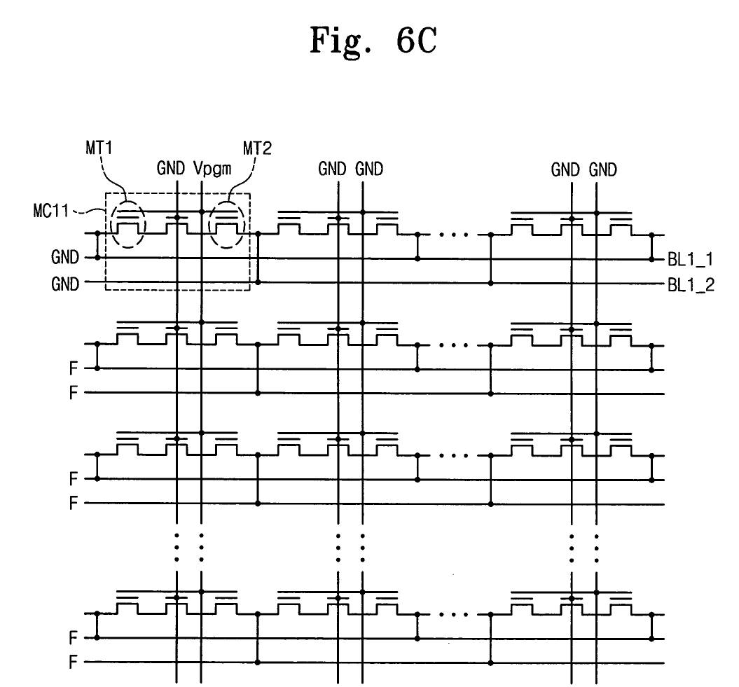

FIGS. 6A to 6C illustrate program bias conditions applied to the nonvolatile memory device of FIG. 5. The nonvolatile memory device shown in FIG. 5 may be programmed using a Fowler-Nordheim (FN) tunneling mechanism. Referring to FIG. 5 and FIG. 6A, a method of programming the first memory transistor MT1 of the memory cell unit MC11 will now be described.

In order to selectively program the first memory transistor MT1 of the memory cell unit MC11, a program voltage Vpgm may be applied to the first word line WL1, which is connected to the memory cell unit MC11, and a ground voltage GND may be applied to the remaining word lines WL2˜WLn. The program voltage Vpgm may be about 10 V to about 20 V. Further, all of the isolation gate lines IL1˜ILn may be grounded to prevent a program disturbance between the first and second memory transistors MT1 and MT2 of the memory cell unit MC11. In addition, the first bit line BL1_1 connected to the memory cell unit MC11 may be grounded, and the remaining first bit lines BL2_1, . . . and BLm_1 and all the second bit lines BL1_2, . . . and BLm_2 may be floated. Accordingly, electrons may be selectively injected into the first memory gate of the memory cell unit MC11.

Referring to FIG. 5 and FIG. 6B, a method of programming the second memory transistor MT2 of the memory cell unit MC11 will now be described. In order to selectively program the second memory transistor MT2 of the memory cell unit MC11, the program voltage Vpgm may be applied to the first word line WL1, which is connected to the memory cell unit MC11, and the ground voltage GND may be applied to the remaining word lines WL2˜WLn. The program voltage Vpgm may be about 10 V to about 20 V. Further, all the isolation gate lines IL1˜ILn may be grounded to prevent a program disturbance between the first and second memory transistors MT1 and MT2 of the memory cell unit MC11. In addition, the second bit line BL1_2 connected to the memory cell unit MC11 may be grounded, and the remaining second bit lines BL2_2, . . . and BLm_2 and all the first bit lines BL1_1, . . . and BLm_1 may be floated. Accordingly, electrons may be selectively injected into the second memory gate of the memory cell unit MC11.

Referring to FIG. 5 and FIG. 6C, a method of programming both the first and second memory transistors MT1 and MT2 of the memory cell unit MC11 will now be described. In order to program the first and second memory transistors MT1 and MT2 of the memory cell unit MC11, the program voltage Vpgm may be applied to the first word line WL1, which is connected to the memory cell unit MC11, and the ground voltage GND may be applied to the remaining word lines WL2—WLn. The program voltage Vpgm may be about 10 V to about 20 V. Further, all of the isolation gate lines IL1˜ILn may be grounded. In another implementation, all of the isolation gate lines IL1˜ILn may be floated. In addition, the first and second bit lines BL1_1 and BL1_2 connected to the memory cell unit MC11 may be grounded, and the remaining first bit lines BL2_1, . . . and BLm_1 and the remaining second bit lines BL2_2, . . . and BLm_2 may be floated. Accordingly, electrons may be selectively injected into both the first and second memory gates MG1 and MG2 of the memory cell unit MC11. In this case, even though the isolation gate lines IL1˜ILn are floated, the program disturbance between the first and second memory transistors MT1 and MT2 of the memory cell unit MC11 may not occur because both the first and second memory transistors MT1 and MT2 are simultaneously programmed.

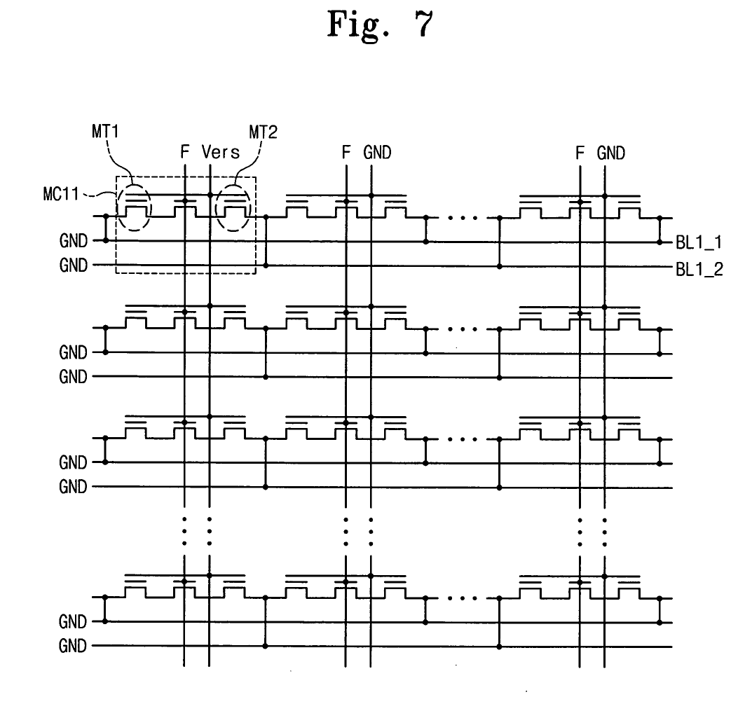

FIG. 7 illustrates an erasure bias condition applied to the nonvolatile memory device of FIG. 5. Referring to FIG. 5 and FIG. 7, a method of erasing the memory cell unit MC11 will now be described.

In order to erase the memory cell unit MC11, an erasure voltage Vers may be applied to the first word line WL1, which is connected to the memory cell unit MC11, and the ground voltage GND may be applied to the remaining word lines WL2˜WLn. The erasure voltage Vers may be about −10 V to about −20 V (about minus 10 V to about minus 20 V). Further, all of the isolation gate lines IL1˜ILn may be floated, and all of the first and second bit lines BL1_1, . . . , BLm_1, BL1_2, . . . , and BLm_2 may be grounded. Accordingly, electrons in the first and second memory gates MG1 and MG2 of the memory cell unit MC11 may be selectively injected into the semiconductor substrate.

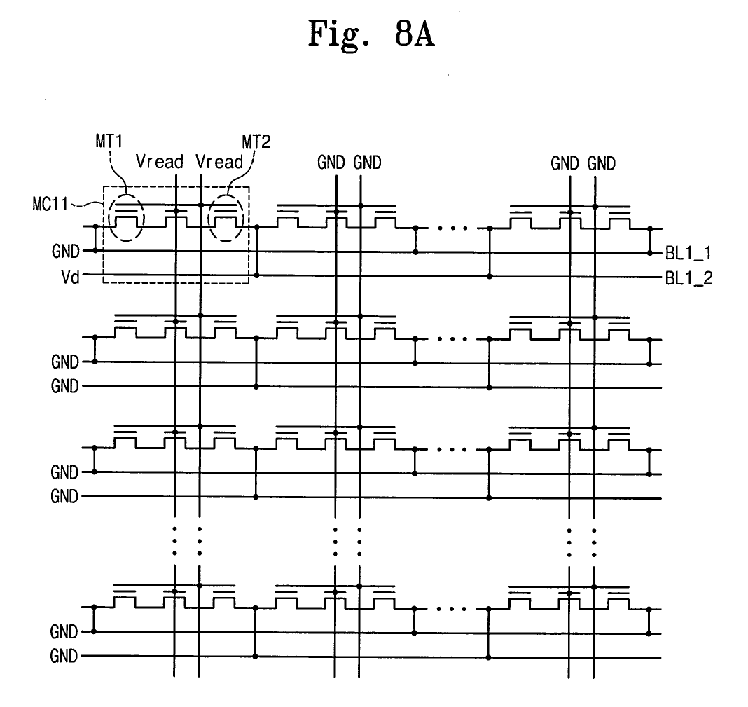

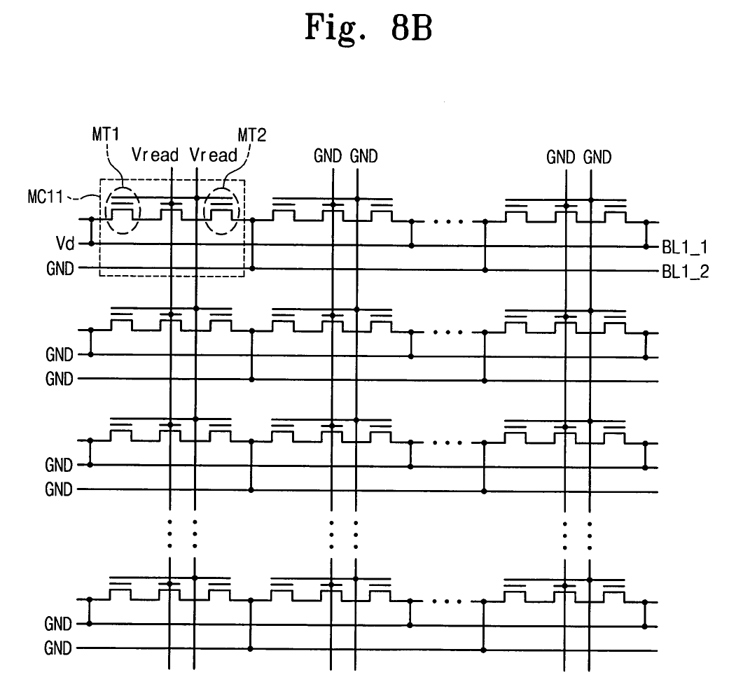

FIG. 8A illustrates a bias condition to selectively read out a data stored in the first memory transistor MT1 of the memory cell unit MC11 of the nonvolatile memory device shown in FIG. 5, and FIG. 8B illustrates a bias condition to selectively read out a data stored in the second memory transistor MT2 of the memory cell unit MC11 of the nonvolatile memory device shown in FIG. 5. Each memory cell unit of FIG. 5 may have the same structure as illustrated in FIG. 2.

Referring to FIG. 2, FIG. 5 and FIG. 8A, a read voltage Vread may be selectively applied to the first word line WL1 and the first isolation gate line IL1 connected to the memory cell unit MC11. The read voltage Vread may be, e.g., about 0.5 V to about 3V. In some implementations, the read voltage Vread applied to the first word line WL1 may differ from the read voltage Vread applied to the first isolation gate line IL1. Further, the remaining word lines WL2˜WLn and the remaining isolation gate lines IL2˜ILn may be grounded, and all the first bit lines BL1_1˜BLm_1 may also be grounded. That is, the ground voltage GND may be applied to the word lines WL2˜WLn and the isolation gate lines IL2˜ILn.

In addition, a drain voltage Vd may be selectively applied to the second bit line BL1_2 connected to the memory cell unit MC11, and the remaining second bit lines BL2_2˜BLm_2 may be grounded. Accordingly, the drain voltage Vd may be applied to the second impurity region 150b of the selected memory cell unit MC11 through the second bit line BL1_2.

The drain voltage Vd may be, e.g., about 0.5 V to about 1V. Moreover, the semiconductor substrate 100 may also be grounded. Therefore, a reverse bias may be applied between the second impurity region 150b of the memory cell unit MC11 and the semiconductor substrate 100. As a result, a depletion region may be formed at an interface between the second impurity region 150b of the selected memory cell unit MC11 and the semiconductor substrate 100, and the depletion region may be expanded into a channel region 150c below the second memory gate 120b (MG2) of the memory cell unit MC11. Thus, when electrons are stored in the first memory gate MG1 of the memory cell unit MC11, the selected memory cell unit MC11 may be turned off to prevent a read current from flowing through the second bit line BL1_2. In another implementation, when the first memory transistor MT1 of the selected memory cell unit MC11 is erased to have an initial threshold voltage or lower, the selected memory cell unit MC11 may be turned on to allow the read current to flow through the second bit line BL1_2. Thus, the memory system may discriminate as to whether the first memory transistor MT1 of the selected memory cell unit MC11 is programmed or erased by detecting the read current that flows through the second bit line BL1_2 under the read bias condition described above.

Referring to FIG. 2, FIG. 5 and FIG. 8B, a method of selectively reading a data stored in the second memory transistor MT2 of the memory cell unit MC11 will now be described. The read method illustrated in FIG. 8B is different from that in FIG. 8A only in terms of the bias condition applied to the first and second bit lines BL1_1 and BL1_2 connected to the selected memory cell unit MC1. In particular, the drain voltage Vd and the ground voltage GND may be respectively applied to the first and second bit lines BL1_1 and BL1_2 in order to selectively read out the data stored in the second memory transistor MT2 of the memory cell unit MC11.

If the drain voltage Vd and the ground voltage GND are applied to the first and second bit lines BL1_1 and BL1_2 as illustrated in FIG. 8B, a reverse bias may be applied between the first impurity region 150a of the memory cell unit MC11 and the semiconductor substrate 100. As a result, a depletion region may be formed at an interface between the first impurity region 150a of the selected memory cell unit MC11 and the semiconductor substrate 100, and the depletion region may be expanded into the channel region 150c below the first memory gate 120a (MG1) of the memory cell unit MC11. Thus, the memory system may discriminate as to whether the second memory transistor MT2 of the selected memory cell unit MC11 is programmed or erased by detecting the read current that flows through the first bit line BL1_1 under the read bias condition described above.

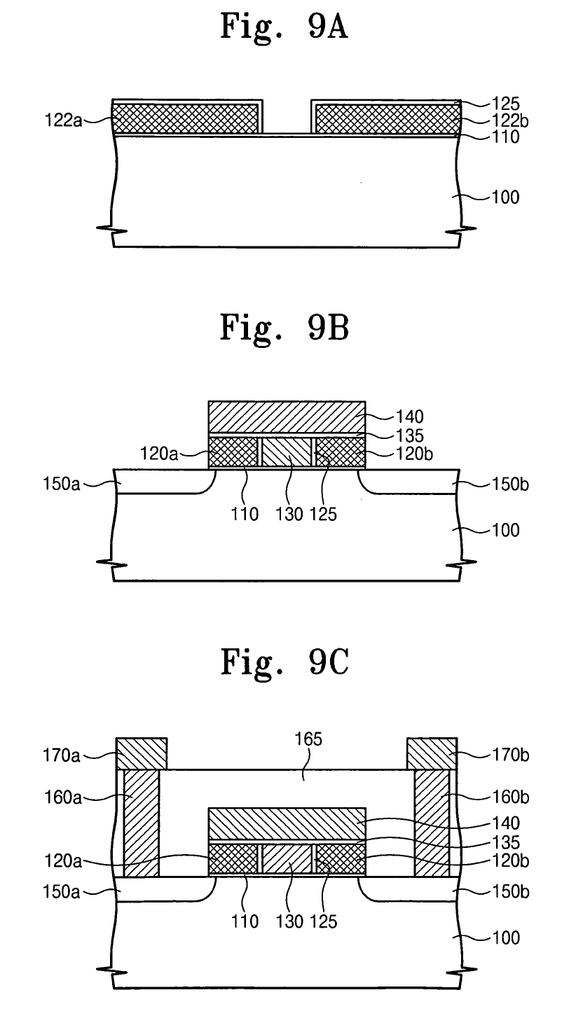

FIGS. 9A to 9C illustrate cross sectional views of stages in a method of forming a nonvolatile memory device according to an embodiment.

Referring to FIG. 9A, a tunnel insulation layer 110 may be formed on the semiconductor substrate 100. The tunnel insulation layer 110 may be formed using, e.g., a thermal oxidation technique.

A first preliminary memory gate pattern 122a and a second preliminary memory gate pattern 122b may be formed on the tunnel insulation layer 110. The first and second preliminary memory gate patterns 122a and 122b may be formed to be spaced apart from each other. The first and second preliminary memory gate patterns 122a and 122b may be formed of, e.g., a polysilicon layer.

The first inter-gate dielectric layer 125 may be formed on the first and second preliminary memory gate patterns 122a and 122b. The first inter-gate dielectric layer 125 may be formed using, e.g., a thermal oxidation technique or a chemical vapor deposition technique, which may be conformal.

Referring to FIG. 9B, the isolation gate line 130 may be formed to fill the space between the first inter-gate dielectric layer 125 on the first preliminary memory gate pattern 122a and the first inter-gate dielectric layer 125 on the second preliminary memory gate pattern 122b. The isolation gate line 130 may be formed of, e.g., a polysilicon layer. Formation of the isolation gate line 130 may include forming an isolation gate layer (not shown) on the first inter-gate dielectric layer 125, and planarizing the isolation gate layer to expose the first and second preliminary memory gate patterns 122a and 122b.

The second inter-gate dielectric layer 135 may be formed on the first and second preliminary memory gate patterns 122a and 122b as well as on the isolation gate line 130. The second inter-gate dielectric layer 135 may be formed of, e.g., a silicon oxide layer, an oxide-nitride-oxide (ONO) layer, or an aluminum oxide layer.

The word line 140 may be formed on the second inter-gate dielectric layer 135. The word line 140 may be formed to fully overlap the isolation gate line 130 and to extend across unit cells in parallel with the isolation gate line 130. In addition, the word line 140 may be formed to partially or fully overlap the first preliminary memory gate pattern 122a and the second preliminary memory gate pattern 122b that are adjacent to the isolation gate line 130. The word line 140 may be formed of a conductive layer, e.g., a polysilicon layer.

In an implementation, the first and second preliminary memory gate patterns 122a and 122b may be patterned after forming the word line 140 to form a first memory gate 120a and a second memory gate 120b at both sides of the isolation gate line 130. The first and second memory gates 120a and 120b may thus be self-aligned with the word line 140, as illustrated in FIG. 9B. In an implementation, the first and second memory gates 120a and 120b may be formed by etching the first and second preliminary memory gate patterns 122a and 122b using the word line 140 as an etching mask.

Impurity ions may be injected into the semiconductor substrate 100 using the word line 140 as a mask. As a result, the first impurity region 150a may be formed in the semiconductor substrate 100 adjacent to the first memory gate 120a, and the second impurity region 150b may be formed in the semiconductor substrate 100 adjacent to the second memory gate 120b.

Referring to FIG. 9C, the first interlayer dielectric layer 165 may be formed to cover the word line 140, the first impurity region 150a and the second impurity region 150b. The first bit line contact 160a and the second bit line contact 160b may be formed in the first interlayer dielectric layer 165. The first and second bit line contacts 160a and 160b may be electrically connected to the first and second impurity regions 150a and 150b, respectively. The first bit line 170a and the second bit line 170b may be formed on the first interlayer dielectric layer 165. The first and second bit lines 170a and 170b may be electrically connected to the first and second bit line contacts 160a and 160b, respectively.

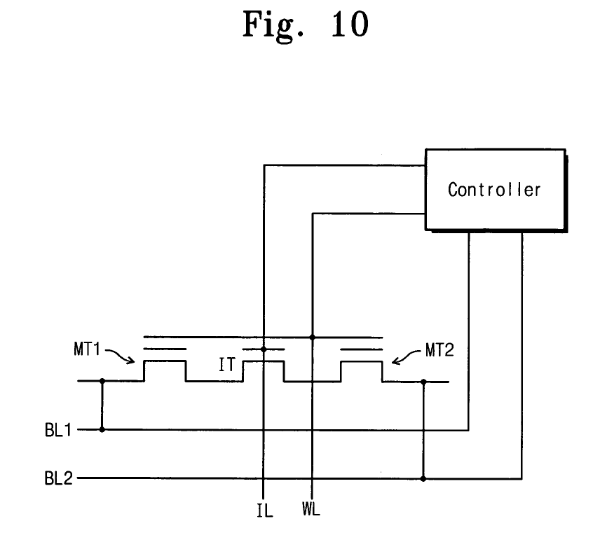

FIG. 10 illustrates a schematic of a memory system according to an embodiment. The system may include, e.g., one or more of the devices described above in connection with FIGS. 4A to 4C coupled to a controller. The controller may be coupled to the word lines 140 (WL), the isolation gate lines 130 (IL), and the first and second bit lines (BL1 and BL2) of the respective memory devices. The controller may control the signals applied to the respective memory devices, and may be configured to provide the program bias conditions described in connection with FIGS. 6A to 6C, the erasure bias condition described in connection with FIG. 7, and the read bias conditions described in connection with FIGS. 8A and 8B.

In a nonvolatile memory device and associated methods according to embodiments, a program disturbance between the first memory gate MG1 and the second memory gate MG2 may be suppressed by the isolation gate line IL. Further, each memory cell unit of the nonvolatile memory device may store two bits of data. Accordingly, the degree of integration of the nonvolatile memory device may be increased. Further, the nonvolatile memory device may be both programmed and erased by a Fowler-Nordheim (FN) tunneling mechanism, which may provide good long-term reliability and low power consumption.

Example embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A nonvolatile memory device, comprising:
a semiconductor substrate; and
a plurality of memory cell units on the substrate, wherein each of the memory cell units includes:
a tunnel insulation layer on the substrate,
a first memory gate and a second memory gate on the tunnel insulation layer, the first and second memory gates being spaced apart from each other,
an isolation gate line between the first and second memory gates, and
a word line on the first memory gate, the second memory gate, and the isolation gate line.

2. The nonvolatile memory device as claimed in claim 1, further comprising a first inter-gate dielectric layer between the first memory gate and the isolation gate line, and between the second memory gate and the isolation gate line.

3. The nonvolatile memory device as claimed in claim 2, further comprising a second inter-gate dielectric layer between the first memory gate and the word line, between the second memory gate and the word line, and between the isolation gate line and the word line.

4. The nonvolatile memory device as claimed in claim 1, wherein:
the word line is coupled to first and second memory gates, and
the isolation gate line extends between the first and second memory gates.

5. The nonvolatile memory device as claimed in claim 1, wherein:
the substrate includes an active region,
the active region includes at least one protruding extension part,
an impurity region extends into the extension part, and
a bit line contact is electrically connected to the impurity region, the electrical connection being at least partially in the extension part.

6. A nonvolatile memory system, including:
a semiconductor substrate;
a plurality of memory cell units on the substrate; and
a memory controller electrically connected to the plurality of memory cell units, wherein each of the memory cell units includes:
a tunnel insulation layer on the substrate,
a first memory gate and a second memory gate on the tunnel insulation layer, the first and second memory gates being spaced apart from each other,
an isolation gate line between the first and second memory gates, and
a word line on the first memory gate, the second memory gate, and the isolation gate line.

7. The nonvolatile memory system as claimed in claim 6, wherein the controller is configured to program and erase the memory cell units using Fowler-Nordheim tunneling.

8. The nonvolatile memory system as claimed in claim 6, wherein the controller is configured to float the isolation gate line of a selected memory cell unit during a program operation that writes data to both the first and second memory gates of the selected memory cell unit.

9. The nonvolatile memory system as claimed in claim 6, wherein the controller is configured to apply a ground voltage to the isolation gate line of a selected memory cell unit during a program operation that writes data to one of the first and second gates of the selected memory cell unit.

10. The nonvolatile memory system as claimed in claim 9, wherein, during the program operation, the controller:
applies a program voltage to the word line of the selected memory cell unit, and
applies a ground voltage to a bit line electrically connected to a selected memory transistor that includes the first memory gate of the selected memory cell unit when writing data to the first memory gate.

11. The nonvolatile memory system as claimed in claim 9, wherein the controller is configured to float the isolation gate line of the selected memory cell unit during an erase operation that erases data from the selected memory cell unit.

12. The nonvolatile memory system as claimed in claim 11, wherein, during the erase operation, the controller:
applies an erasure voltage to the word line of the selected memory cell unit, and
applies a ground voltage to first and second bit lines electrically connected to respective first and second memory transistors that include the first memory gate and the second memory gate of the selected memory cell unit.

13. The nonvolatile memory system as claimed in claim 9, wherein the controller is configured to apply a read voltage to the word line and the isolation gate line of the selected memory cell unit during a read operation that reads data stored in the selected memory cell unit.

14. The nonvolatile memory system as claimed in claim 13, wherein, during the read operation, the controller:
applies a ground voltage to a bit line coupled to a memory transistor that includes one of the first and second memory gates of the selected memory cell unit,
applies a drain voltage to a bit line electrically connected to a memory transistor that includes the other of the first and second memory gates of the selected memory cell unit, and
applies the ground voltage to the bit line of the memory transistor being read.

15. A method of forming memory cell units on a semiconductor substrate, the method comprising:
forming a tunnel insulation layer on the substrate;
forming a first memory gate and a second memory gate on the tunnel insulation layer, the first and the second memory gates being spaced apart from each other;
forming an isolation gate line between the first and the second memory gates; and
forming a word line on the first memory gate, the second memory gate, and the isolation gate line.

16. The method as claimed in claim 15, wherein forming the first and second memory gates, the isolation gate line, and the word line includes:
forming a first preliminary memory gate pattern and a second preliminary memory gate pattern on the tunnel insulation layer, the first and second preliminary memory gate patterns being spaced apart from each other,
forming the isolation gate line in a space between the first and second preliminary memory gate patterns,
forming the word line on the isolation gate line and on the first and second preliminary memory gate patterns, the word line being formed to fully cover the isolation gate line, and
etching the first and second preliminary memory gate patterns using the word line as an etching mask.

17. The method as claimed in claim 15, further comprising forming a first inter-gate dielectric layer between the first memory gate and the isolation gate line, and between the second memory gate and the isolation gate line.

18. The method as claimed in claim 17, further comprising forming a second inter-gate dielectric layer between the first memory gate and the word line, between the second memory gate and the word line, and between the isolation gate line and the word line.

19. The method as claimed in claim 15, further comprising:
forming an active region in the substrate, the active region including at least one protruding extension part,
forming an impurity region that extends into the extension part, and
forming a bit line contact that is electrically connected to the impurity region, the electrical connection being formed at least partially in the extension part.

20. The method as claimed in claim 15, wherein:
the word line is formed to extend across first and second memory gates of first and second memory cell units, and
the isolation gate line is formed to extend between the first and second memory gates of the first memory cell unit, and between the first and second memory gates of the second memory cell unit.
